(19) United States
(12) Patent Application Publication
(10) Pub. No.: US 2025/0048796 A1
(43) Pub. Date: Feb. 6, 2025

(54) LIGHT-EMITTING ELEMENT

(71) Applicant: NICHIA CORPORATION, Anan-shi (JP)

(72) Inventor: Ryota YAMAMOTO, Komatsushima-shi (JP)

(73) Assignee: NICHIA CORPORATION, Anan-shi (JP)

(21) Appl. No.: 18/785,298

(22) Filed: Jul. 26, 2024

(30) Foreign Application Priority Data
Aug. 4, 2023 (JP) 2023-127938

(51) Int. Cl. H01L 33/38; H01L 33/30; H01L 33/62

(52) U.S. Cl. CPC H01L 33/382; H01L 33/30; H01L 33/62

(57) ABSTRACT

A light-emitting element includes a semiconductor structure including: an n-type semiconductor layer including a first n-type semiconductor layer and a second n-type semiconductor layer, an active layer, and a p-type semiconductor layer. The active layer is located between the n-type semiconductor layer and the p-type semiconductor layer in a thickness direction. An n-side electrode electrically connected to the n-type semiconductor layer. A p-side electrode electrically connected to the p-type semiconductor layer.

### CROSS-REFERENCE TO RELATED APPLICATION

This application claims priority to Japanese Patent Application No. 2023-127938, filed on Aug. 4, 2023, the disclosure of which is hereby incorporated herein by reference in its entirety.

### BACKGROUND

### Technical Field

The invention according to the present disclosure relates to a light-emitting device.

### Background Art

JP 2018-064006 A, for example, proposes a configuration for a red light-emitting device made of an AlGaInP-based semiconductor material, in which an n-side electrode and a p-side electrode are located on one surface, and light is extracted from the opposite surface from the surface with the electrodes. Specifically, JP 2018-064006 A proposes, in a light-emitting device configured with a transparent substrate bonded to the light extraction surface, to provide a surface-roughened transparent film with a lower refraction index than that of the transparent substrate on the surface of the transparent substrate where light is extracted. In this light-emitting device, the roughened surface of the transparent film helps to increase the light distribution angle and light emission efficiency irrespective of the material of the transparent substrate, and the low refraction index of the transparent film material allows total internal reflection to occur, which raises the light emission efficiency even more.

### SUMMARY

An object of the present disclosure is to provide a light-emitting element that allows a reduction of light absorption by semiconductor material while ensuring a favorable electrical connection between electrodes and semiconductor.

The light-emitting element according to the present disclosure includes: a semiconductor structure comprising: an n-type semiconductor layer comprising a first n-type semiconductor layer and a second n-type semiconductor layer, an active layer, and a p-type semiconductor layer. The active layer is located between the n-type semiconductor layer and the p-type semiconductor layer in a thickness direction. An n-side electrode electrically connected to the n-type semiconductor layer. A p-side electrode electrically connected to the p-type semiconductor layer. The active layer is configured to emit red light having a peak wavelength within a range of 620 nm or more and 700 nm or less. The semiconductor structure comprises a first region and a second region in a plan view, the first region being a region where the p-type semiconductor layer and the active layer are located, and the second region being a region other than the first region. The first n-type semiconductor layer is located in the first region and the second region. The second n-type semiconductor layer is located on the first n-type semiconductor layer at a side opposite a p-type semiconductor layer side of the first n-type semiconductor layer, so as to overlap the first n-type semiconductor layer at least in a part of the second region in a plan view. A band gap energy of the second n-type semiconductor layer is smaller than a band gap energy of the first n-type semiconductor layer. A portion of the first n-type semiconductor layer located in the second region has an opening through which the second n-type semiconductor layer is exposed. The n-side electrode is electrically connected to the second n-type semiconductor layer in the opening.

The light-emitting element according to certain embodiments of the present disclosure allows a reduction of light absorption by semiconductor material while ensuring a favorable electrical connection between electrodes and semiconductor.

### BRIEF DESCRIPTION OF DRAWINGS

FIG. 1A is a plan view illustrating a light-emitting element according to Embodiment 1 of the present disclosure.

FIG. 1B is a cross-sectional view along line IB-IB in FIG. 1A that illustrates the light-emitting element according to Embodiment 1 of the present disclosure.

FIG. 1C is a cross-sectional view along line IC-IC in FIG. 1A that illustrates the light-emitting element according to Embodiment 1 of the present disclosure.

FIG. 2 is a plan view illustrating a first region and a second region of a semiconductor structure that forms the light-emitting element according to Embodiment 1 of the present disclosure.

FIG. 3 is a plan view illustrating p-side electrodes of the light-emitting element according to Embodiment 1 of the present disclosure.

FIG. 4 is a plan view illustrating openings in one insulation film that forms the light-emitting element according to Embodiment 1 of the present disclosure.

FIG. 5 is a plan view illustrating openings in another insulation film that forms the light-emitting element according to Embodiment 1 of the present disclosure.

FIG. 6 is a plan view illustrating a wiring layer that forms the light-emitting element according to Embodiment 1 of the present disclosure.

FIG. 7 is a plan view illustrating an n-side pad electrode and a p-side pad electrode that form the light-emitting element according to Embodiment 1 of the present disclosure.

FIG. 8 is a plan view illustrating a light-emitting element according to Embodiment 2 of the present disclosure.

FIG. 9 is a plan view illustrating a first region, a second region, and p-side electrodes in the light-emitting element according to Embodiment 2 of the present disclosure.

FIG. 10 is a plan view illustrating openings in one insulation film that forms the light-emitting element according to Embodiment 2 of the present disclosure.

FIG. 11 is a plan view illustrating a wiring layer, an n-side pad electrode, a p-side pad electrode, and another insulation film, which form the light-emitting element, as well as openings in the another insulation film, according to Embodiment 2 of the present disclosure.

FIG. 12 is a cross-sectional view illustrating a light-emitting element according to Embodiment 3 of the present disclosure.

FIG. 13A is a cross-sectional view illustrating a step of a method of manufacturing the light-emitting element according to Embodiment 1 of the present disclosure.

FIG. 13B is a cross-sectional view illustrating a step of a method of manufacturing the light-emitting element according to Embodiment 1 of the present disclosure.

FIG. 13C is a cross-sectional view illustrating a step of a method of manufacturing the light-emitting element according to Embodiment 1 of the present disclosure.

FIG. 13D is a cross-sectional view illustrating a step of a method of manufacturing the light-emitting element according to Embodiment 1 of the present disclosure.

FIG. 13E is a cross-sectional view illustrating a step of a method of manufacturing the light-emitting element according to Embodiment 1 of the present disclosure.

FIG. 13F is a cross-sectional view illustrating a step of a method of manufacturing the light-emitting element according to Embodiment 1 of the present disclosure.

FIG. 13G is a cross-sectional view illustrating a step of a method of manufacturing the light-emitting element according to Embodiment 1 of the present disclosure.

FIG. 13H is a cross-sectional view illustrating a step of a method of manufacturing the light-emitting element according to Embodiment 1 of the present disclosure.

FIG. 13I is a cross-sectional view illustrating a step of a method of manufacturing the light-emitting element according to Embodiment 1 of the present disclosure.

FIG. 13J is a cross-sectional view illustrating a step of a method of manufacturing the light-emitting element according to Embodiment 1 of the present disclosure.

FIG. 13K is a cross-sectional view illustrating a step of a method of manufacturing the light-emitting element according to Embodiment 1 of the present disclosure.

FIG. 13L is a cross-sectional view illustrating a step of a method of manufacturing the light-emitting element according to Embodiment 1 of the present disclosure.

FIG. 13M is a cross-sectional view illustrating a step of a method of manufacturing the light-emitting element according to Embodiment 1 of the present disclosure.

FIG. 13N is a cross-sectional view illustrating a step of a method of manufacturing the light-emitting element according to Embodiment 1 of the present disclosure.

FIG. 13O is a cross-sectional view illustrating a step of a method of manufacturing the light-emitting element according to Embodiment 1 of the present disclosure.

### DETAILED DESCRIPTION

### Embodiment 1

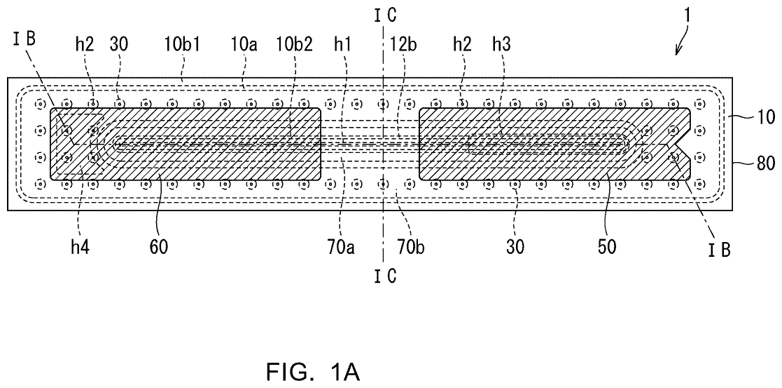

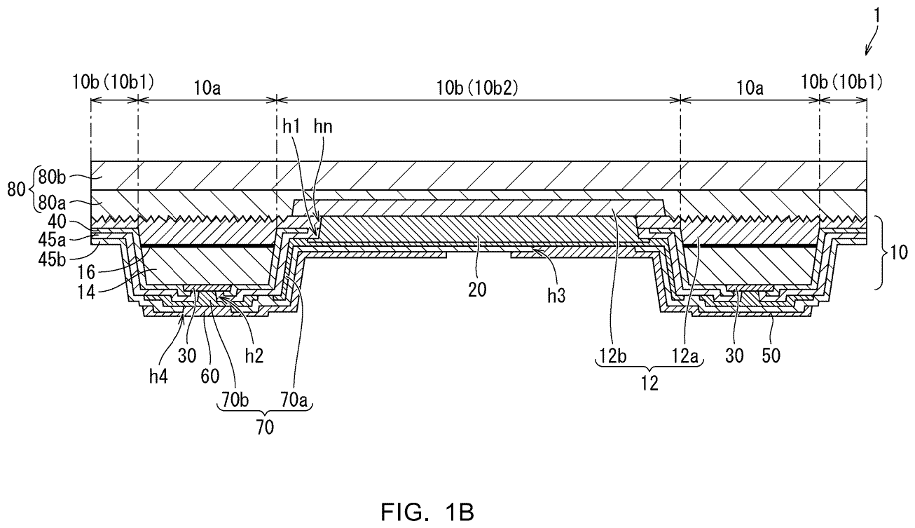

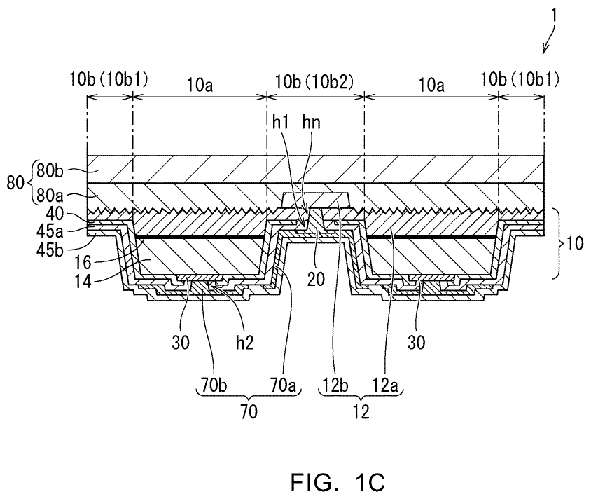

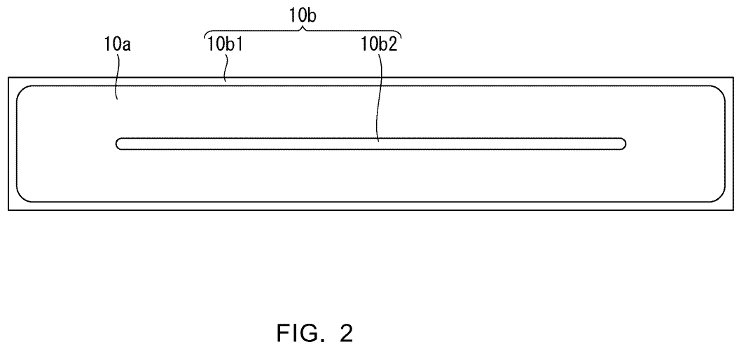

FIG. 1A to FIG. 7 each show a first embodiment of the light-emitting element according to the present disclosure, either in a cross-sectional or plan view. FIG. 1A is a plan view of the light-emitting element according to this embodiment. FIG. 1B is a cross-sectional view along line IB-IB in FIG. 1A. FIG. 1C is a cross-sectional view along line IC-IC in FIG. 1A. FIG. 2 shows only the first region and second region to be described later, clarifying their positional relationship in a plan view. As shown in these drawings, the light-emitting element 1 of this embodiment includes a semiconductor structure 10, an n-side electrode 20, and p-side electrodes 30. The semiconductor structure includes an n-type semiconductor layer 12 including a first n-type semiconductor layer 12a and a second n-type semiconductor layer 12b, a p-type semiconductor layer 14, and an active layer 16 located between the n-type semiconductor layer 12 and the p-type semiconductor layer 14. The light-emitting element 1 further includes a dielectric multilayer film 40, insulation films 45a and 45b, an n-side pad electrode 50, a p-side pad electrode 60, and a wiring layer 70 for connecting the n-side electrode 20 and the p-side electrodes 30 to the n-side pad electrode 50 and the p-side pad electrode 60, respectively. The light-emitting element 1 includes a holding part 80 that supports the semiconductor structure 10 on the opposite surface from the side where the n-side pad electrode 50 and the p-side pad electrode 60 are located. The light emitted from the active layer 16 of the light-emitting element 1 is mainly extracted from the side where the holding part 80 is located.

The semiconductor structure 10 has a first region 10a and a second region 10b in a plan view. The first region 10a is a region where the p-type semiconductor layer 14 and active layer 16 are located. The second region 10b, which is a region other than the first region 10a, is where the semiconductor structure 10 has the n-type semiconductor layer 12 alone. In this embodiment, the second region 10b includes an outer peripheral portion 10b1 along the outer edges of the light-emitting element 1 in a plan view, and a center portion 10b2 substantially in the center of the light-emitting element 1. In the light-emitting element 1 of this embodiment, the n-type semiconductor layer 12 is located such that, while the first n-type semiconductor layer 12a is located both in the first region 10a and second region 10b, the second n-type semiconductor layer 12b is located at least partly in the second region 10b. As shown in FIG. 1A, the second n-type semiconductor layer 12b is located inside the center portion 10b2 of the second region 10b. The second n-type semiconductor layer 12b is located at the opposite side from the p-type semiconductor layer 14 when viewed from the first n-type semiconductor layer 12a, i.e., the second n-type semiconductor layer 12b is closer to a support substrate 80b (described below), than is the first n-type semiconductor layer 12a.

The first n-type semiconductor layer 12a has an opening hn in the center portion 10b2 of the second region 10b, so that the second n-type semiconductor layer 12b is exposed in the opening hn. Here, Component x being exposed from Component y, or, Component y exposing Component x, shall mean that, while Component x is covered by Component y in one part, Component x is not covered by Component y in another part, allowing the part that is not covered by Component y to be covered by another component. In this embodiment, in the opening hn, the n-side electrode 20 is electrically connected to the second n-type semiconductor layer 12b, and the n-side electrode 20 is further electrically connected to the n-side pad electrode 50 via the wiring layer 70.

In this embodiment, the active layer 16 emits red light having a peak wavelength within a range of 620 nm or more and 700 nm or less. Semiconductor materials forming a semiconductor structure and allowing such red light to be emitted tend to absorb more light from the active layer 16 when they have a smaller band gap energy. On the other hand, forming the n-type semiconductor layer 12 using only a semiconductor material having higher band gap energy may be disadvantageous from the point of view of reducing contact resistance between semiconductor material and metal, i.e., reducing the forward voltage Vf of the light-emitting element. Therefore, in this embodiment, a material having a smaller band gap energy than that of the first n-type semiconductor layer 12a is used for the second n-type semiconductor layer 12b, and the second n-type semiconductor layer 12b is entirely located within the second region 10b that does not overlap the active layer 16 in a plan view. Moreover, the n-side electrode 20 is located in contact with the second n-type semiconductor layer 12b, and electrically connected to the second n-type semiconductor layer 12b. This configuration can reduce interference between the light from the active layer and the semiconductor material, which, while easily absorbing red light, offers advantage in terms of contact resistance with the n-side electrode 20. As a result, red light absorption can be reduced without increasing the forward voltage Vf of the light-emitting element 1, allowing the light-emission efficiency of the light-emitting element 1 to be improved. Namely, light absorption by the semiconductor material in the light-emitting element 1 can be reduced while a favorable electrical connection is ensured between the n-side electrode 20 and the semiconductor material. In this embodiment, the center portion 10b2 of the second region 10b where the second n-type semiconductor layer 12b is located is surrounded by the first region 10a in a plan view. This arrangement can minimize an unevenness in the current density distribution in the light-emitting element 1.

In this embodiment, the second n-type semiconductor layer 12b may not entirely be located inside the second region 10b and may partly be located in the first region 10a in a plan view. There may be two or more second regions 10b that are surrounded by the first region 10a in a plan view. For example, there may be a plurality of substantially oblong second regions 10b such as the one shown in FIG. 1A. Alternatively, the second region 10b may include the center portion 10b2 and a plurality of regions radially extending from the center portion 10b2 in a plan view.

It is preferable that, in a plan view, the second n-type semiconductor layer 12b has outer edges of a shape corresponding to that of the outer edges of the second region 10b, and all the outer edges of the second n-type semiconductor layer 12b are positioned inside the second region 10b. Forming the second n-type semiconductor layer 12b in the shape corresponding to the shape of the second region 10b facilitates the arrangement of the first region 10a and second region 10b in consideration of the current density distribution and the positions of light-emitting regions.

Hereinafter, the embodiment will be described more specifically.

### 1. Semiconductor Structure

The semiconductor structure 10 includes the n-type semiconductor layer 12 including the first n-type semiconductor layer 12a and the second n-type semiconductor layer 12b, the p-type semiconductor layer 14, and the active layer 16 located between the n-type semiconductor layer 12 and the p-type semiconductor layer 14. In FIG. 1B and FIG. 1C, the semiconductor structure 10 is shown with the p-type semiconductor layer 14 being the lower side, and the light extraction surface (the surface at the side with the holding part 80) being the upper side. While the semiconductor structure 10 in this embodiment is rectangular in a plan view, the semiconductor structure 10 may have another shape, such as square, circle, trapezoid, triangle, or polygons having five or more sides. In the case where the semiconductor structure 10 has a polygonal shape with a plurality of corners in a plan view, these polygon corners may be rounded.

The semiconductor materials that form the semiconductor structure 10 are selected such that the active layer 16 emits red light having a peak wavelength within a range of 620 nm or more and 700 nm or less. In this embodiment, the semiconductor materials that form the p-type semiconductor layer 14, active layer 16, and first n-type semiconductor layer 12a may contain an AlGaInP-based material, for example. An AlGaInP-based material can be expressed by the formula (AlₓGa₁ₓ)_{y}In_{1-y}P (0≤x≤1, 0≤y≤1), for example. The peak wavelength of red light is adjusted by changing the ratio of Al and Ga in the semiconductor material that forms the active layer 16. In this embodiment, materials expressed by the above formula in the range of (0.1≤x≤0.5, 0.1≤y≤0.5) may be used to form the active layer 16 (or, when the active layer 16 has a multilayer structure, one of the layers).

The p-type semiconductor layer 14 may include a plurality of layers. The p-type semiconductor layer 14 may for example include a p-type contact layer, a p-type clad layer, and a p-type intermediate layer, sequentially from the bottom in FIG. 1B and FIG. 1C. The p-type contact layer is intended to establish a secure electrical connection with the p-side electrodes 30 and to spread the current. A GaP-based semiconductor material that is one of AlGaInP-based materials and does not contain Al and In, may be used for the p-type contact layer, for example. The p-type contact layer may have a thickness of 0.1 μm or more and 1 μm or less. The clad layer is intended to accelerate the recombination of electrons and holes in the active layer 16. An AlInP-based semiconductor material may be used for the clad layer, for example. The p-type clad layer may have a thickness of 0.1 μm or more and 1 μm or less. The p-type intermediate layer is intended to mitigate the diffusion of impurities in the p-type semiconductor layer 14 into the active layer. An AlGaInP-based semiconductor material may be used for the p-type intermediate layer, for example. The p-type intermediate layer may have a thickness of 0.1 μm or more and 0.5 μm or less.

The active layer 16 may have a multiple quantum well structure including a plurality of well layers and a plurality of barrier layers. In this case, a GaInP-based material may be used for the well layers, and an AlGaInP-based material may be used for the barrier layers. One well layer may have a thickness of 1 nm or more and 10 nm or less. One barrier layer may have a thickness of 10 nm or more and 50 nm or less. The well layers and barrier layers may repeatedly alternate such that there are 5 or more and 20 or less well layers. The active layer 16 may have an overall thickness of 5 μm or more and 10 μm or less, for example.

The first n-type semiconductor layer 12a of the n-type semiconductor layer 12 may be formed by a plurality of layers. In this case, the materials of respective layers are selected in accordance with the purposes they serve. The n-type layer may for example include an n-type intermediate layer, an n-type clad layer, and a current diffusion layer, sequentially from the bottom in FIG. 1B and FIG. 1C. The n-type intermediate layer is intended to mitigate the migration of impurities in the n-type semiconductor layer 12 into the active layer 16. An AlGaInP-based semiconductor material may be used for the n-type intermediate layer, for example. The n-type intermediate layer may have a thickness of 0.1 μm or more and 0.5 μm or less. The n-type clad layer is intended to accelerate the recombination of electrons and holes in the active layer 16, similarly to the p-type clad layer described above. An AlInP-based semiconductor material may be used for the n-type clad layer, for example. The n-type clad layer may have a thickness of 0.1 μm or more and 1 μm or less. The current diffusion layer is intended to diffuse the current. An AlGaInP-based semiconductor material may be used for the current diffusion layer, for example. The current diffusion layer may have a thickness of 1 μm or more and 3 μm or less.

The first n-type semiconductor layer 12a in the second region 10b may have a thickness of 1 μm or more and 2 μm or less, for example. With the first n-type semiconductor layer 12a having a thickness of 1 μm or more, the risk of cracking in the semiconductor structure 10 can be reduced. With the first n-type semiconductor layer 12a having a thickness of 2 μm or less, light absorption by the first n-type semiconductor layer 12a can be lowered.

The second n-type semiconductor layer 12b contains a semiconductor material having a smaller band gap energy than that of the first n-type semiconductor layer 12a. For example, when the first n-type semiconductor layer 12a is a layer that contains an AlGaInP-based material, the second n-type semiconductor layer 12b may be formed to contain an AlGaAs-based material. An AlGaAs-based material can be expressed by the formula AlzGaizAs (0≤z≤1), for example. In this embodiment, from the point of view of reducing contact resistance, GaAs (Z=1 in the above formula) is preferably used.

An AlGaInP-based material has a band gap energy of about 1.91 eV or more and 2.23 eV or less. An AlGaAs-based material has a band gap energy of about 1.42 eV or more and 2.16 eV or less. For example, GaAs has a band gap energy of about 1.4 eV. The contact resistance between an AlGaAs-based material and metal is generally lower than that between an AlGaInP-based material and metal. Therefore, an AlGaAs-based material is preferably used when the layers from the p-type semiconductor layer 14 to the first n-type semiconductor layer 12a are made of an AlGaInP-based material.

The second n-type semiconductor layer 12b may have a thickness of 0.05 μm or more and 0.5 μm or less, for example. With the second n-type semiconductor layer 12b having a thickness of 0.05 μm or more, the sheet resistance of the second n-type semiconductor layer 12b can be reduced. With the second n-type semiconductor layer 12b having a thickness of 0.5 μm or less, light absorption by the second n-type semiconductor layer 12b can be lowered.

The area of the second n-type semiconductor layer 12b may be, for example, 3% or more and 10% or less of the area of the light-emitting element 1, in a plan view. This range of area allows the light absorption by the second n-type semiconductor layer 12b to be reduced while ensuring the electrical connection between the second n-type semiconductor layer 12b and the n-side electrode 20.

The semiconductor structure 10 includes a region where the p-type semiconductor layer 14 and active layer 16 are located. The first n-type semiconductor layer 12a includes a region where the p-type semiconductor layer 14 and active layer 16 are not located. In this region, the first n-type semiconductor layer 12a is exposed from the p-type semiconductor layer 14 and active layer 16. In this embodiment, the region where the p-type semiconductor layer 14 and active layer 16 are located in the semiconductor structure 10 in a plan view is referred to as the first region 10a, and the region other than the first region 10a is referred to as the second region 10b. As shown in FIG. 2, the second region 10b is surrounded by the first region 10a in a plan view. The second region 10b includes an outer peripheral portion 10b1 located near the outer edges of the light-emitting element 1, and a center portion 10b2 located substantially in the center of the light-emitting element 1.

The first region 10a is the main light-emitting region of the light-emitting element 1 and therefore, the first region 10a is preferably made as large as possible to ensure a certain amount of emitted light. On the other hand, the center portion 10b2 of the second region 10b where the second n-type semiconductor layer 12b is located is the part where the n-side electrode 20 and the n-type semiconductor layer 12 are electrically connected. In the light emitting element 1 having a rectangular shape in a plan view, the first region 10a may be formed to occupy, for example, 70% or more of the area of the light-emitting element 1, and the second region 10b may be formed to occupy, for example, 10% or more and 30% or less of the area of the light-emitting element 1. The second n-type semiconductor layer 12b may be formed to occupy, for example, 10% or more and 20% or less of the area of the second region 10b, in a plan view.

When the light-emitting element 1 is rectangular with short sides of 100 μm or more and 2000 μm or less and long sides of 100 μm or more and 2000 μm or less, the second region 10b may have a substantially oblong center portion 10b2 with short sides of 1 μm or more and 10 μm or less and long sides of 50 μm or more and 1500 μm or less, and an outer peripheral portion 10b1 with a width of 1 μm or more and 15 μm or less from the outer edges of the light-emitting element 1. In this case, the second n-type semiconductor layer 12b may be an oblong with short sides of 1 μm or more and 10 μm or less and long sides of 50 μm or more and 1500 μm or less.

As shown in FIG. 1B and FIG. 1C, the first n-type semiconductor layer 12a has an opening hn located in the center portion 10b2 of the second region 10b. The second n-type semiconductor layer 12b is exposed from the first n-type semiconductor layer 12a in the opening hn. The opening hn may have a shape and an area in a plan view such that 60% or more and 90% or less of the surface of the second n-type semiconductor layer 12b is exposed, for example.

As shown in FIG. 1B and FIG. 1C, the first n-type semiconductor layer 12a has a rough surface on the opposite side from the p-type semiconductor layer 14 in the area where the first n-type semiconductor layer 12a does not overlap the second n-type semiconductor layer 12b in a plan view. This is intended to reduce total reflection of light from the active layer 16, thereby to increase the light extraction efficiency. The rough surface of the first n-type semiconductor layer 12a may have an Ra (arithmetic average roughness) of 0.05 μm or more, for example. The rough surface of the first n-type semiconductor layer 12a may comprise protrusions or indentations that are irregular in shape and arrangement, or may comprise protrusions or indentations that are regular in shape and arrangement. Alternatively, the rough surface may contain both of irregularly shaped and arranged protrusions or indentations, and regularly shaped and arranged protrusions or indentations.

### 2. N-Side Electrode

The n-side electrode 20 is located inside the opening hn, in contact with the second n-type semiconductor layer 12b that is exposed from the first n-type semiconductor layer 12a, i.e., in electrical connection with the n-type semiconductor layer 12. As will be described later, the n-side electrode 20 is electrically connected to the wiring layer 70, and electrically connected to the n-side pad electrode 50 via the wiring layer 70.

The n-side electrode 20 is located inside the opening hn of the first n-type semiconductor layer 12a and inside an opening h1 of an insulation film 45a to be described later. A portion of the n-side electrode 20 covers a lower surface of the insulation film 45a in FIG. 1B and FIG. 1C. The n-side electrode 20 overlaps the second n-type semiconductor layer 12b in a plan view.

The n-side electrode 20 may be made of a material containing at least one metal selected from, for example, Au, Ag, Al, Ni, Pd, Ge, Si, and Sn, or may be made of an alloy wherein one or a plurality of these metals are contained as a component(s), for example. The n-side electrode 20 may have a laminated structure. More specifically, the n-side electrode 20 may have a laminated structure in which AuGe, Ni, Ti, Pt, and Ti are sequentially stacked from the side closer to the second n-type semiconductor layer 12b. The n-side electrode 20 may have a thickness of 100 nm or more and 500 nm or less, for example.

### 3. P-Side Electrode

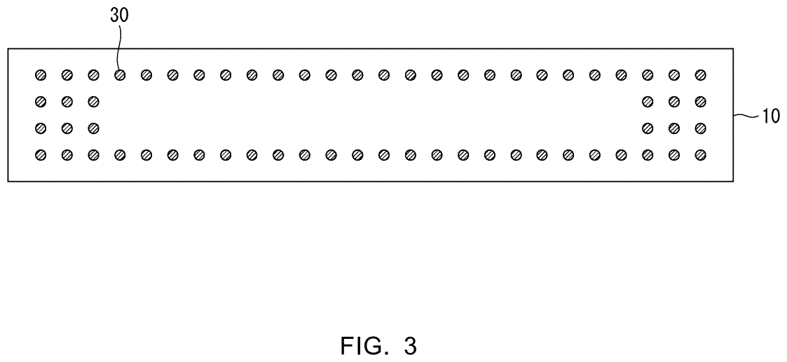

The p-side electrodes 30 are located lowermost in the p-type semiconductor layer 14 in FIG. 1B and FIG. 1C. As shown in FIG. 3, there are a plurality of p-side electrodes 30 on the semiconductor structure 10. The p-side electrodes 30 have a circular shape in a plan view, for example. The p-side electrodes 30 are regularly arranged at equal distance from each other in a plan view. This arrangement can reduce unevenness in the current density distribution in the light-emitting element 1, as well as reduce the light absorption by the p-side electrodes 30. In the case where the p-side electrodes 30 have a circular shape in a plan view, the p-side electrodes 30 of 3 μm or more and 20 μm or less in diameter, for example, may be arranged at a distance of 30 μm or more and 100 μm or less (distance between the centers of adjacent p-side electrodes 30). Alternatively, the p-side electrodes 30 may be arranged in an irregular manner.

In another embodiment, the p-side electrodes 30 may be located over the entire lowermost surface of the p-type semiconductor layer 14 in FIG. 1B and FIG. 1C. In this case, the current can be diffused over a wider area via the p-side electrodes 30, so that unevenness in the current density distribution can be reduced even more.

The p-side electrodes 30 may be made of a material containing at least one metal selected from, for example, Au, Ag, Al, Ni, Pd, Ge, Si, In, and Sn, or may be made of an alloy wherein one or a plurality of these metals are contained as a component(s), for example. A material containing In, Sn, and O and having conductivity may be particularly used for the p-side electrodes 30. A material containing In, Sn, and O may be so-called ITO. Electrodes made of a material containing In, Sn, and O have high transmissivity to the peak wavelength of light from the active layer 16, and therefore, the electrodes of such material are preferably used as the p-side electrodes 30. The p-side electrodes 30 may have a laminated structure. The p-side electrodes 30 may have a thickness of 10 nm or more and 100 nm or less, for example.

### 4. Dielectric Multilayer Film and Insulation Film

The light-emitting element 1 of this embodiment is configured with an n-side pad electrode 50 and a p-side pad electrode 60 located on the same side of the semiconductor structure 10. In this embodiment, a dielectric multilayer film 40, insulation films 45a and 45b, and a wiring layer 70 to be described later are used to provide electrical insulation between the n-side electrode 20 and the p-side electrodes 30, as well as to establish electrical connection of these electrodes to the n-side pad electrode 50 and the p-side pad electrode 60, to allow the n-side pad electrode 50 and the p-side pad electrode 60 to be located at desired positions and in desired shapes irrespective of the positions of the n-side electrode 20 and the p-side electrodes 30.

The dielectric multilayer film 40 and insulation films 45a and 45b are located on the semiconductor structure 10. The dielectric multilayer film 40 is a DBR (Distributed Bragg Reflector) film made of alternating high- and low-refractive index dielectric layers. The dielectric multilayer film 40 is made of combinations of high- and low-refractive index dielectric layers such as Nb₂O₅ layer and SiO₂ layer, or TiO₂ layer and SiO₂ layer, ten or more and thirty or less sets of these combinations being repeatedly stacked. In one combination of high- and low-refractive index dielectric layers, each dielectric layer may have a thickness of 100 nm or more and 200 nm or less. The dielectric multilayer film 40 is located so as to cover substantially the entire surface on the lower side of the semiconductor structure 10 in FIG. 1B and FIG. 1C in a plan view, except for the regions where the n-side electrode 20 and the p-side electrodes 30 are electrically connected to the wiring layer 70. Alternatively, an insulation film may be located instead of providing the dielectric multilayer film 40.

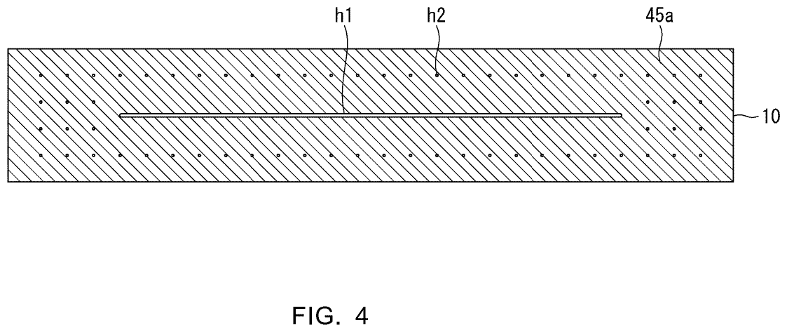

The insulation film 45a is located on the lower surface of the dielectric multilayer film 40 in FIG. 1B and FIG. 1C. The insulation film 45a has an opening h1 that overlaps the opening hn of the first n-type semiconductor layer 12a in a plan view, and openings h2 that overlap the p-side electrodes 30 located on the p-type semiconductor layer 14. The n-side electrode 20 is located inside the opening h1, and the p-side electrodes 30 are electrically connected to the wiring layer 70 in the openings h2. As shown in FIG. 2 and FIG. 4, the opening h1 is located so as to overlap the center portion 10b2 of the second region 10b in a plan view. As shown in FIG. 1A, the openings h2 have a circular shape, similar to the p-side electrodes 30, and are located at positions corresponding to the p-side electrodes 30.

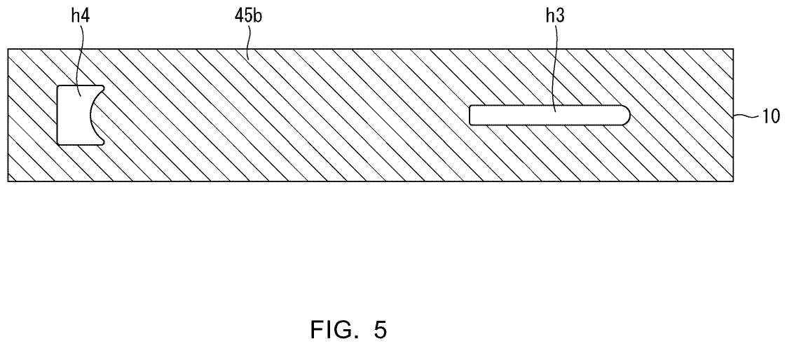

The insulation film 45b provides electrical insulation between an n-side wiring portion 70a connected to the n-side electrode 20 and a p-side wiring portion 70b connected to the p-side electrodes 30. As shown in FIG. 1A, FIG. 1B, and FIG. 5, the insulation film 45b has an opening h3 and an opening h4, the n-side pad electrode 50 being electrically connected to the wiring layer 70 in the opening h3, and the p-side pad electrode 60 being electrically connected to the wiring layer 70 in the opening h4. The insulation film 45b is located between the n-side and p-side pad electrodes 50 and 60 and the wiring layer 70 so as to provide electrical insulation between the n-side pad electrode 50 and the p-side pad electrode 60 in portions other than the opening h3 and the opening h4. The opening h3 has an area in a plan view of 5000 μm² or more and 10000 μm² or less, for example. The opening h4 has an area in a plan view of 1000 μm² or more and 5000 μm² or less, for example.

A material selected from SiO₂, SiN, and SiON may be used for the insulation films 45a and 45b. A SiO₂ film has high transmissivity to the peak wavelength of light from the active layer 16, and therefore, the SiO₂ film is preferably used as the insulation films 45a and 45b. Each of the insulation films 45a and 45b may have a thickness of 0.1 μm or more and 1 μm or less. The insulation films 45a and 45b may be made of different materials, or the same material.

### 5. Wiring Layer

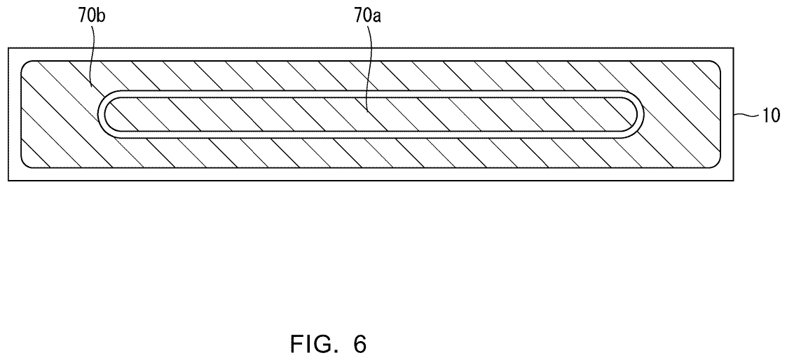

The wiring layer 70 serves to electrically connect the n-side electrode 20 to the n-side pad electrode 50, and electrically connect the p-side electrodes 30 to the p-side pad electrode 60. As shown in FIG. 1B, FIG. 1C, and FIG. 6, the wiring layer 70 includes an n-side wiring portion 70a connected to the n-side electrode 20 and a p-side wiring portion 70b connected to the p-side electrodes 30 in a plan view.

The wiring layer 70 may be made of a material containing at least one metal selected from, for example, Au, Cu, and Al, or may be made of an alloy wherein one or a plurality of these metals are contained as a component(s), for example. The wiring layer 70 is located over a relatively wide area on the semiconductor structure 10 in a plan view as shown in FIG. 1A and FIG. 6, and therefore, the wiring layer 70 is preferably made of a material that has high transmissivity to the light emitted from the active layer 16. Au, for example, is preferably used for the wiring layer 70. The wiring layer 70 may have a thickness of 100 nm or more and 500 nm or less.

The positions and other features of dielectric multilayer film 40, insulation films 45a and 45b, and wiring layer 70 are not limited to the illustrated example. As long as the n-side electrode 20 and the p-side electrodes 30 are respectively connected to the n-side pad electrode 50 and p-side pad electrode 60, three or more insulation films may be located in the thickness direction, and a plurality of wiring layers 70 may be located in the thickness direction. The positions and shapes of the openings in the insulation films 45a and 45b are not limited to any particular ones.

### 6. Pad Electrode

The n-side pad electrode 50 and p-side pad electrode 60 are portions electrically connected to an external power supply. The n-side pad electrode 50 is electrically connected to the n-side wiring portion 70a in the opening h3 of the insulation film 45b, and the p-side pad electrode 60 is electrically connected to the p-side wiring portion 70b in the opening h4 of the insulation film 45b.

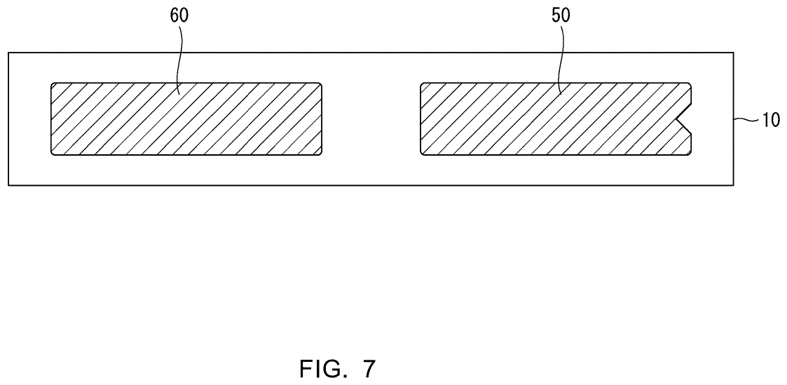

The n-side pad electrode 50 and the p-type side electrode 60 have substantially the same rectangular shape in a plan view as shown in FIG. 1A and FIG. 7, and are located substantially symmetrically on the left and right sides of the light-emitting element 1 in the drawing. In a plan view, the n-side pad electrode 50 and the p-side pad electrode 60 each have an area corresponding to, for example, 20% or more and 40% or less of the area of the light-emitting element 1 in a plan view.

The n-side pad electrode 50 and the p-side pad electrode 60 may be made of a material containing at least one metal selected from, for example, Au, Ag, Pt, Ti, Ni, Ge, Rh, and Ru, or may be made of an alloy, in particular an eutectic, wherein one or a plurality of these metals are contained as a component(s), for example. Examples of eutectics used for the n-side pad electrode 50 and the p-side pad electrode 60 include Au—Sn eutectic and Ag—Sn eutectic. Each of the n-side pad electrode 50 and the p-side pad electrode 60 may have a thickness of 100 nm or more and 500 nm or less.

### 7. Holding Part

The holding part 80 can protect the semiconductor structure 10 and enhance the mechanical strength of the light-emitting element 1. After growing the semiconductor structure 10 on a growth substrate, the growth substrate is removed. The holding part 80 is then located on the surface of the light-emitting element 1 at the side with the n-type semiconductor layer 12, i.e., to replace the growth substrate. When the holding part 80 with high transmissivity to the peak wavelength of light from the active layer 16 is located in such a manner, the holding part 80 can help to increase the amount of extracted light because light is extracted from the side with the n-type semiconductor layer 12.

In this embodiment, the holding part 80 includes a bonding member 80a and a support substrate 80b. The bonding member 80a is made of SiO₂, for example. The bonding member 80a may have a thickness of 0.5 μm or more and 2 μm or less.

In this embodiment, a sapphire substrate, or a glass substrate or the like, can be used as the support substrate 80b. A sapphire substrate is preferably used as the support substrate 80b due to its high mechanical strength and high transmissivity to the peak wavelength of light from the active layer 16. The support substrate 80b may have a thickness of 500 μm or more and 1000 μm or less.

The configuration and materials of the holding part 80 are not limited to those described above. For example, the holding part may have a single-layer structure made solely of a SiO₂ layer. In the case where the holding part 80 has a single-layer structure made solely of a SiO₂ layer, the holding part 80 may have a thickness of 0.5 μm or more and 2 μm or less.

### Embodiment 2

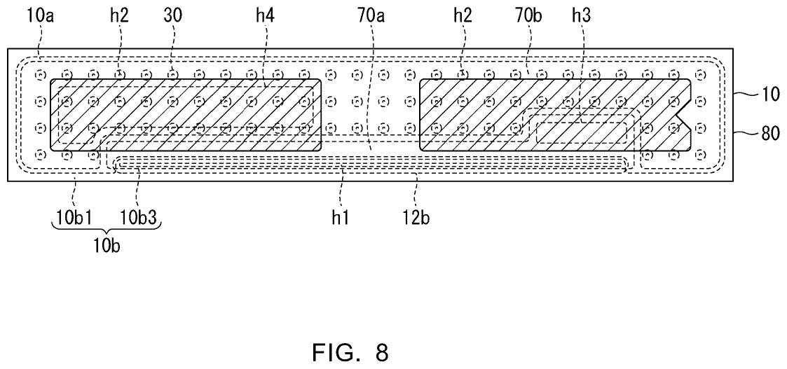

Next, a second embodiment will be described. In the following description and in FIG. 8 to FIG. 11, the components to be described with reference to the same symbols as in Embodiment 1 are the same components as those of Embodiment 1, and the descriptions associated with Embodiment 1 shall apply to these components except for parts that differ from Embodiment 1.

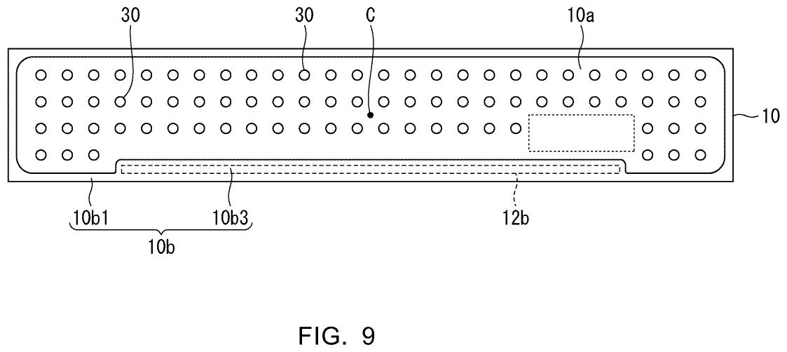

One example of arrangement of the first region 10a, second region 10b, and second n-type semiconductor layer 12b will be described as Embodiment 2 with reference to FIG. 8 to FIG. 11. In the light-emitting element according to Embodiment 2, the first region 10a of the semiconductor structure 10 is a region including the center C of the light-emitting element 1 in a plan view as shown in FIG. 8 and FIG. 9. The second n-type semiconductor layer 12b does not overlap the center C of the light-emitting element 1 in a plan view. The second region 10b is shaped to include an outer peripheral portion 10b1, and an extended portion 10b3 continuous with the outer peripheral portion 10b1 and extending from the outer peripheral portion 10b1 toward the center C of the light-emitting element. The second n-type semiconductor layer 12b (indicated with a broken line in FIG. 8 and FIG. 9) is located inside the extended portion 10b3 in a plan view. While Embodiment 1 has a configuration in which the center portion 10b2 of the second region 10b and the second n-type semiconductor layer 12b are located substantially in the center of the light-emitting element 1, Embodiment 2 corresponds to an embodiment that is changed from Embodiment 1 such that the center portion 10b2 of the second region 10b and the second n-type semiconductor layer 12b are located closer to the longer side positioned at the lower side of FIG. 8 and FIG. 9 of the semiconductor structure 10. This configuration allows the first region 10a containing the active layer 16 to be located in the center region of the light-emitting element in a plan view, and facilitates light emission from the center region of the light-emitting element. The area of the second n-type semiconductor layer 12b may be 50% or more and 70% or less of the area of the extended portion 10b3, in a plan view. This range of area allows the light absorption by the second n-type semiconductor layer 12b to be reduced while ensuring the electrical connection between the second n-type semiconductor layer 12b and the n-side electrode 20.

The extended portion 10b3 may have a shape and size in a plan view that are the same as the center portion 10b2 of the second region 10b described above in Embodiment 1. The outer peripheral portion 10b1 may have a shape and size in a plan view that are the same as the outer peripheral portion 10b1 of the second region 10b described above in Embodiment 1.

With the second region 10b and second n-type semiconductor layer 12b being located closer to one longer side of the semiconductor structure 10 in a plan view in Embodiment 2, Embodiment 2 are different from Embodiment 1 in the shape and/or arrangement of the p-side electrodes 30, opening hn, n-side electrode 20, openings h1, h2, and h3, and wiring layer 70, as shown in FIG. 8 to FIG. 10.

As shown in FIG. 9, in Embodiment 2, the p-side electrodes 30 have a circular shape in top view, similarly to Embodiment 1. The p-side electrodes 30 are located around the center C where there is no second region 10b, and are not located in a region surrounded by a dotted line as shown in FIG. 9. This is because an n-side wiring portion 70a is located in this portion, as will be described later, for the convenience of locating the n-side pad electrode 50.

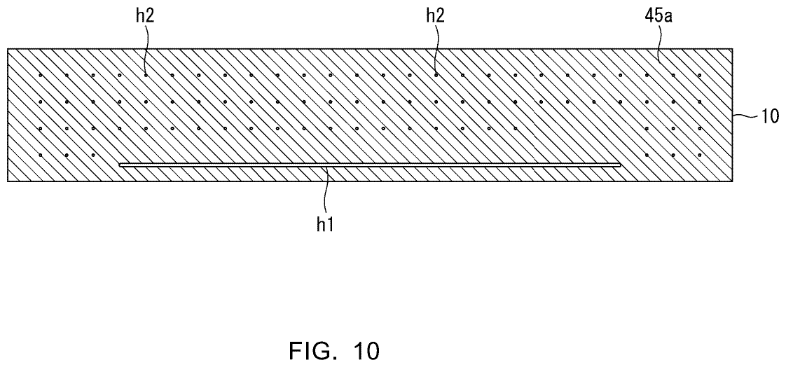

As shown in FIG. 10, the insulation film 45a is located so as to cover substantially the entire surface on the light-emitting element on the dielectric multilayer film 40 (not shown), except for in the openings h1 and h2 where the wiring layer 70 is electrically connected to the n-side electrode 20 and the p-side electrodes 30. In this embodiment, the openings h1 are circular to match the shape of the p-side electrodes 30 and arranged in corresponding positions similarly to Embodiment 1. The opening h2 is located so as to overlap the opening hn (not shown) formed in the first n-type semiconductor layer 12a, similarly to Embodiment 1.

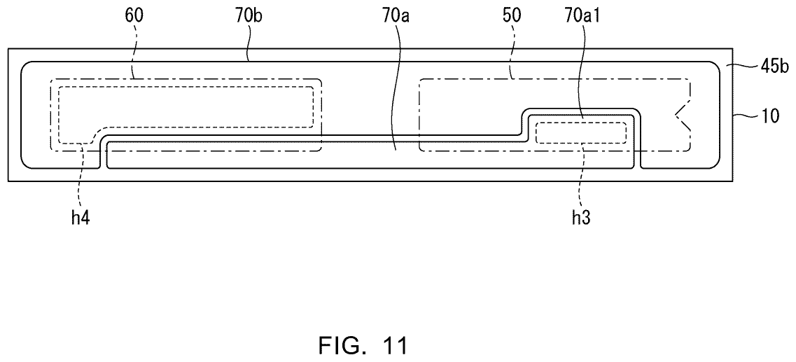

As shown in FIG. 9 and FIG. 11, the n-side wiring portion 70a covers substantially the entire extended portion 10b3 of the second region 10b, and includes an extended portion 70al extending toward the first region 10a, in a plan view. The extended portion 70al is used for electrical connection with the n-side pad electrode 50 as will be described later. The p-side wiring portion 70b is located to overlap the region where the p-side electrodes 30 shown in FIG. 9 are arranged, in the first region 10a.

The insulation film 45b includes an opening h3 where the extended portion 70al of the n-side wiring portion 70a is electrically connected to the n-side pad electrode 50, and an opening h4 where the p-side electrodes 30 are electrically connected to the p-side pad electrode 60. In FIG. 11, the shapes and arrangement of the openings h3 and h4 are depicted with broken lines, and the n-side pad electrode 50 and the p-side pad electrode 60 are depicted with one-dot chain lines.

The reason why the opening h3 is located to overlap the extended portion 70al of the wiring layer 70 is to allow the n-side pad electrode 50 to be shaped and arranged similarly to Embodiment 1, with the second n-type semiconductor layer 12b being offset as illustrated. In Embodiment 2, the n-side pad electrode 50 would also have to be shifted or made larger to overlap the second n-type semiconductor layer 12b, in order to realize a configuration in which the opening h4 is located to overlap the second n-type semiconductor layer 12b as in Embodiment 1 is realized.

The opening h4 of Embodiment 2 has a larger area in a plan view than the opening h4 of Embodiment 1. The opening h4 is positioned closer to the center region of the light-emitting element as compared to the light-emitting element 1 of Embodiment 1. This is because, in this embodiment, there is no second region 10b in the center region of the light-emitting element, and because the p-side electrodes 30 are located also in the center region of the light-emitting element. Increasing the area of the opening h4 in a plan view ensures the electrical connection between the wiring layer 70 and the p-side pad electrode 60, and therefore, between the p-side electrodes 30 and the p-side pad electrode 60. For example, the area of the opening h4 may be 60% or more and 90% or less of the area of the p-side pad electrode 60, in a plan view.

According to this embodiment, as mentioned above, the light-emitting element 1 can have a light-emitting region substantially in the center in a plan view. In this embodiment, from the point of view of reducing unevenness in the current density distribution, the second region 10b where the second n-type semiconductor layer 12b is located may be arranged along the two opposite sides of the semiconductor structure 10, or along the four sides of the semiconductor structure 10 in a plan view. Alternatively, the second region may be located at two corners positioned on a diagonal of the semiconductor structure 10 in a plan view. Alternatively, Embodiments 1 and 2 may be combined such that the second region 10b where the second n-type semiconductor layer 12b is located is positioned substantially in the center of the semiconductor structure 10, as well as in a region near an outer edge of the semiconductor structure 10. In this case, the second region 10b positioned substantially in the center of the semiconductor structure 10 may have a smaller area than that of the second region 10b arranged in a region near an outer edge of the semiconductor structure 10.

### Embodiment 3

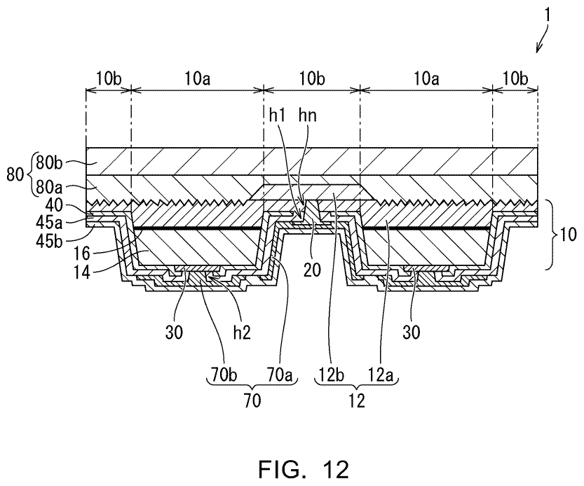

In another embodiment, the second n-type semiconductor layer 12b may be located to partly overlap the first region 10a in a plan view, in order to reduce cracking in the n-type semiconductor layer 12. One example of such an embodiment will be described as Embodiment 3 with reference to FIG. 12. The light-emitting element in Embodiment 3 differs from the light-emitting element of Embodiment 1 in the arrangement of the second n-type semiconductor layer 12b.

In the light-emitting element 1 of Embodiment 3 shown in FIG. 12, the second n-type semiconductor layer 12b is located not only over the entire second region 10b but also extended into the first region 10a. The second n-type semiconductor layer 12b located continuously over the first region 10a and second region 10b has an increased area in a plan view, whereby cracking is less likely to occur. From the point of view of reducing the light absorption by the second n-type semiconductor layer 12b, the portion of the second n-type semiconductor layer 12b located in the first region 10a preferably has an area of 20% or less of the area the entire second n-type semiconductor layer 12b, in a plan view.

Moreover, the portion of the second n-type semiconductor layer 12b located in the first region 10a preferably has a lesser thickness than that of the portion located in the second region 10b. Reducing the thickness of the second n-type semiconductor layer 12b allow the light absorption to be reduced. The portion of the second n-type semiconductor layer 12b located in the first region 10a may have a thickness of 10% or more and 50% or less, for example, of the thickness of the portion of the second n-type semiconductor layer 12b located in the second region 10b. There may be formed a step between the portion of the second n-type semiconductor layer 12b located in the first region 10a and the portion of the second n-type semiconductor layer 12b located in the second region 10b. Alternatively, the second n-type semiconductor layer 12b may decrease in thickness from the boundary between the second region 10b and the first region 10a toward the first region 10a. In this case, the second n-type semiconductor layer 12b has a trapezoidal cross-sectional shape as shown in the drawing.

As long as a least a part of the portion of the second n-type semiconductor layer 12b located in the first region 10a has a thickness less than that of the portion located in the second region 10b, other portions may have the same thickness as that of the portion located in the second region 10b. For example, in the illustrated embodiment, the point where the second n-type semiconductor layer 12b starts to reduce in thickness need not be the exact boundary between the second region 10b and the first region 10a, but may be somewhat offset into the first region 10a or the second region 10b.

### Embodiment 4

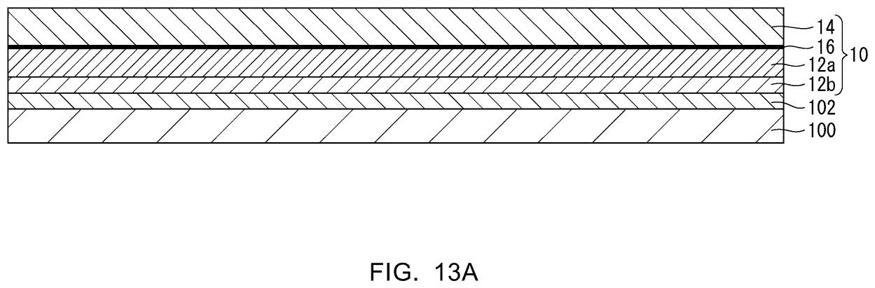

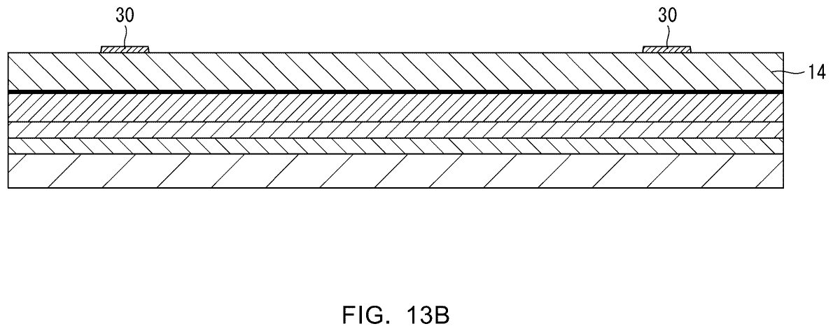

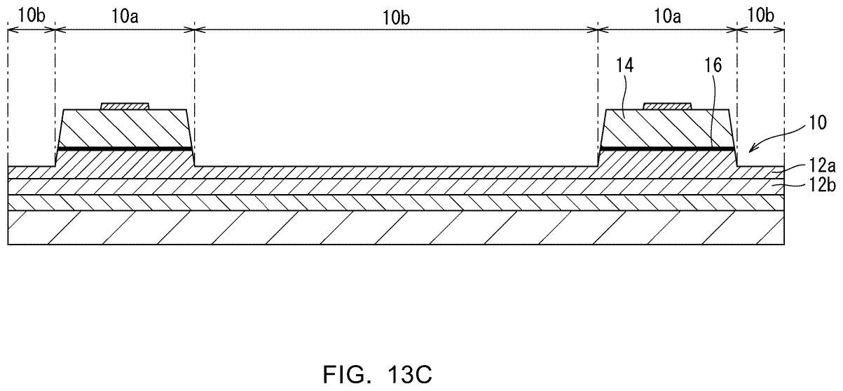

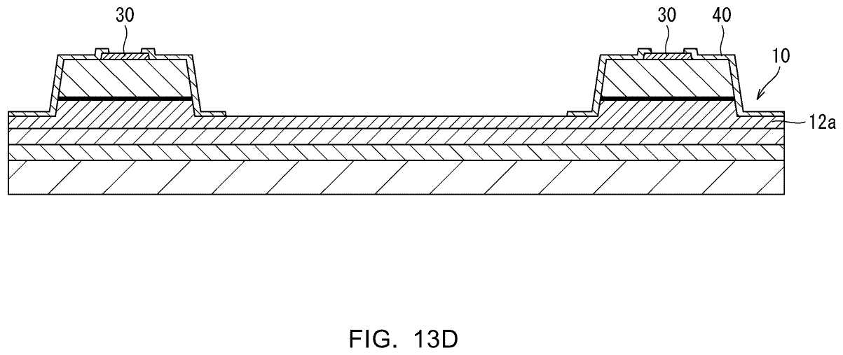

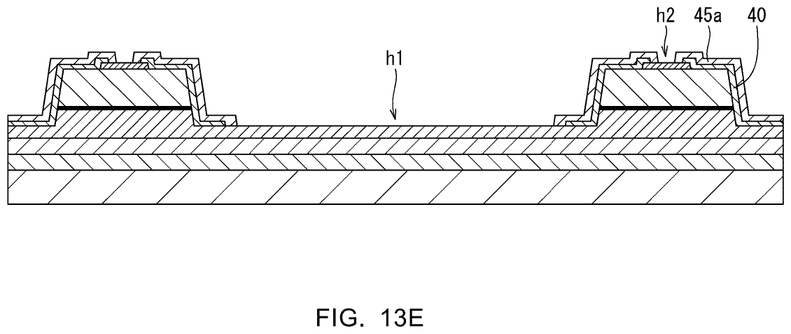

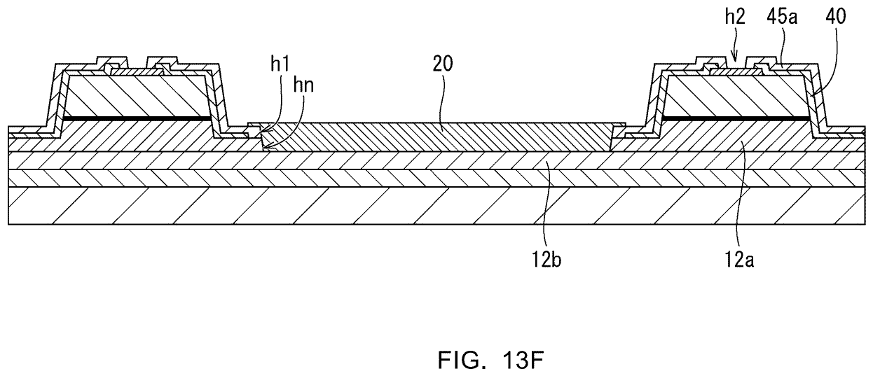

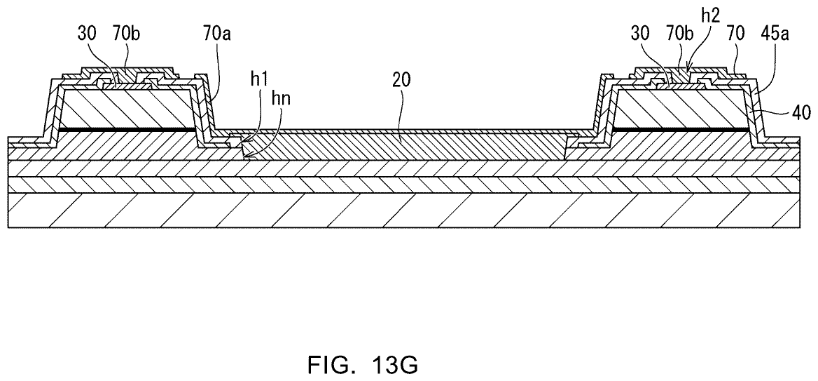

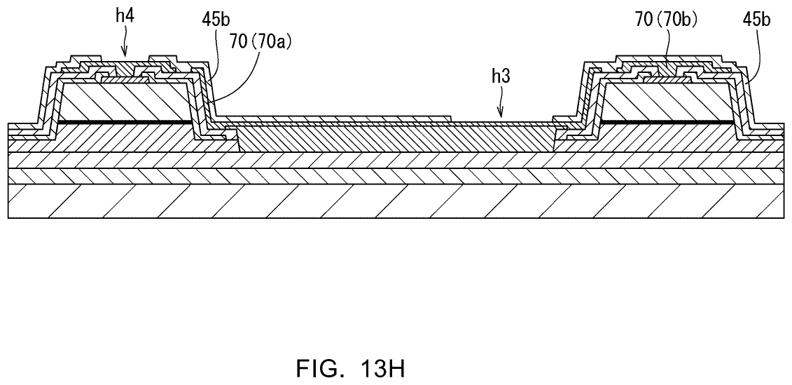

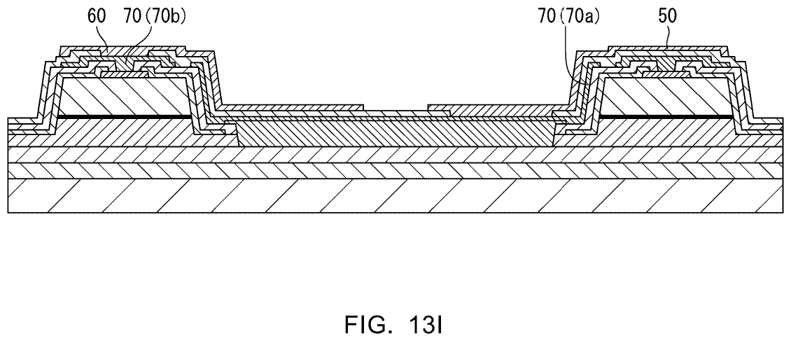

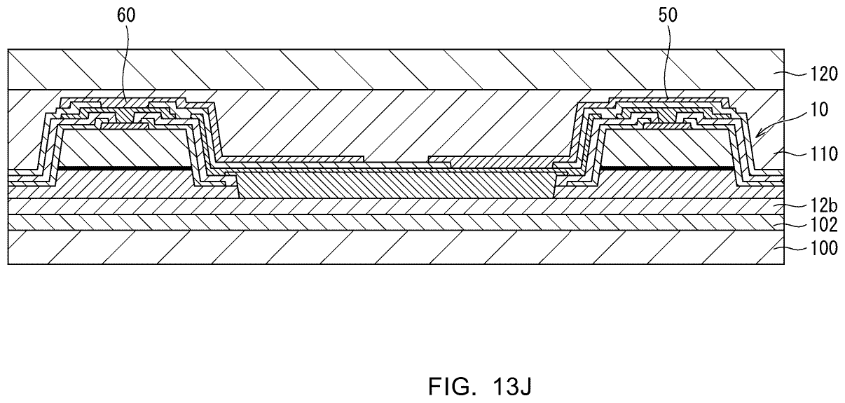

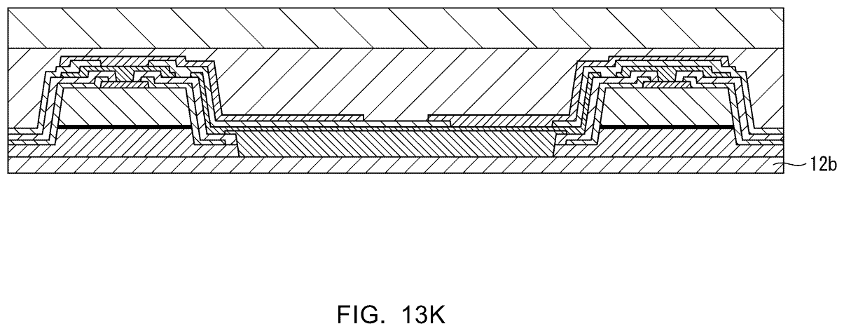

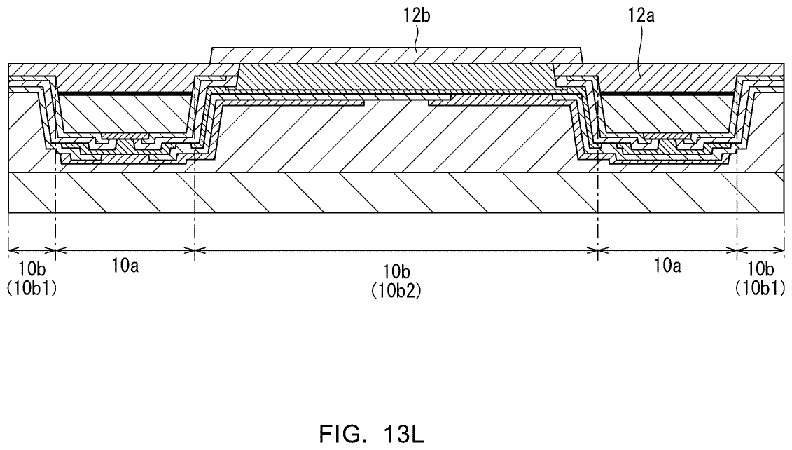

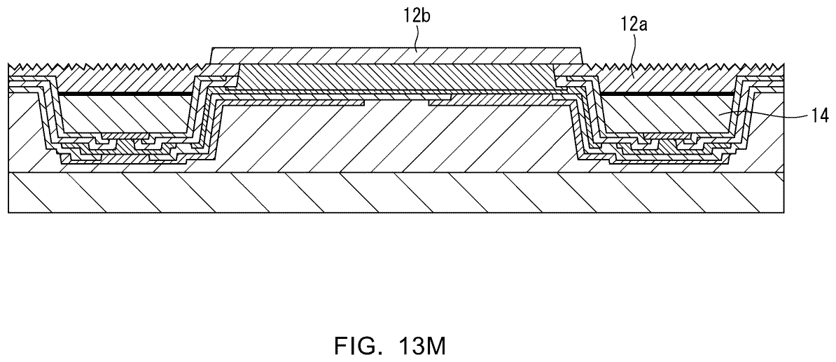

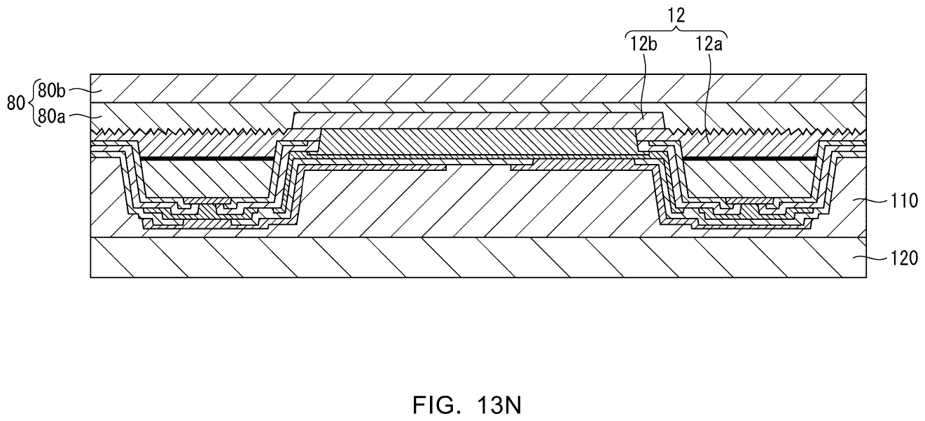

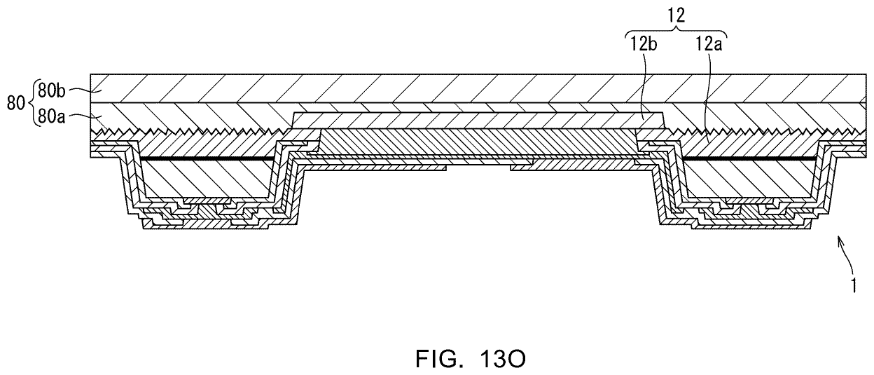

A method of manufacturing the light-emitting element of Embodiment 1 will be described as Embodiment 4 with reference to FIGS. 13A to 13O

As shown in FIG. 13A, a base layer 102 and the semiconductor structure 10 are formed on a GaAs growth substrate 100, the semiconductor structure including the second n-type semiconductor layer 12b, the first n-type semiconductor layer 12a, the active layer 16, and the p-type semiconductor layer 14. The base layer 102 is formed by a GaInP layer, for example, while the second n-type semiconductor layer 12b is formed by a GaAs layer. The first n-type semiconductor layer 12a is formed to include a current diffusion layer, an n-type clad layer, and an n-type intermediate layer sequentially from the base layer 102 side. The current diffusion layer is formed by an AlGaInP layer, the n-type clad layer is formed by an AlInP layer, and the n-type intermediate layer is formed by an AlGaInP layer. The active layer 16 is formed to include an MQW layer wherein GaInP barrier layers and GaInP well layers are alternated. The p-type semiconductor layer 14 is formed to include a p-type intermediate layer, a p-type clad layer, and a p-type contact layer sequentially from the active layer 16 side. The p-type intermediate layer is formed by an AlGaInP layer, the p-type clad layer is formed by an AlInP layer, and the p-type contact layer is formed by a GaP layer. The layers of the semiconductor structure 10 in FIG. 13A may be formed by conventional methods such as, for example, an MOCVD method or an MOVPE method.

Next, as shown in FIG. 13B, the p-side electrodes 30 are formed on the p-type semiconductor layer 14. The p-side electrodes 30 are formed, for example, by forming an ITO layer on the p-type semiconductor layer 14, and removing parts of the ITO layer by wet etching, for example.

Next, parts of the p-type semiconductor layer 14, the active layer 16, and the first semiconductor structure 12a are removed by reactive ion etching or the like, to form the first region 10a with the p-type semiconductor layer 14 and the active layer 16, and the second region 10b without the p-type semiconductor layer 14 and the active layer 16, in the semiconductor structure 10 as shown in FIG. 13C.

Next, the dielectric multilayer film 40 is formed as shown in FIG. 13D. The dielectric multilayer film 40 is formed by a sputtering method or a CVD method or the like, with the material and thickness of each film being suitably selected to provide the function of a DBR film. After forming the dielectric multilayer film 40 so as to cover the semiconductor structure 10, parts of the dielectric multilayer film 40 are removed by wet etching or dry etching or the like, to expose the region of the first n-type semiconductor layer 12a where the n-side electrode 20 is to be located, and a part of each p-side electrode 30 from the dielectric multilayer film 40. Thus, the dielectric multilayer film 40 is formed, with the openings h1 and h2 where the n-side electrode 20 and the p-side electrodes 30 are electrically connected to the wiring layer 70.

Next, an insulation film 45a having openings h1 and h2 is formed on the dielectric multilayer film 40 as shown in FIG. 13E. The insulation film 45a with the openings h1 and h2 is formed by removing parts of the insulation film 45a by wet etching or the like after forming the insulation film 45a so as to cover the dielectric multilayer film 40. The insulation film 45a is formed by a sputtering method or a CVD method.

FIG. 13F shows the step of forming the n-side electrode 20. A part of the first n-type semiconductor layer 12a is removed by reactive ion etching or the like to form the opening hn in the opening h1 so as to expose the second n-type semiconductor layer 12b, and then the n-side electrode 20 is formed on the second n-type semiconductor layer 12b inside the opening h1, with a portion thereof extending over the insulation film 45a. The n-side electrode 20 is formed by a sputtering method, or a deposition method or the like, for example.

FIG. 13G shows the step of forming the wiring layer 70 on the insulation film 45a. The wiring layer 70 is formed so as to electrically connect the n-side electrode 20 and the p-side electrodes 30. The wiring layer 70 is formed inside the openings h2 so as to be electrically connected to the p-side electrodes 30 in the openings h2. The wiring layer 70 is formed such that the n-side wiring portion 70a and the p-side wiring portion 70b are electrically isolated in a plan view. The wiring layer 70 is formed by a sputtering method, or a deposition method or the like.

FIG. 13H shows the step of forming the insulation film 45b. The insulation film 45b is formed on the wiring layer 70. The insulation film 45b is formed so as to make contact with the dielectric multilayer film 40 exposed from the wiring layer 70 between the n-side wiring portion 70a and the p-side wiring portion 70b in a plan view. The insulation film 45b is then partly removed by wet etching or the like to become a film with openings h3 and h4 that expose parts of the wiring layer 70. The insulation film 45b is formed by a sputtering method or a CVD method.

FIG. 13I shows the step of forming the n-side pad electrode 50 and the p-side pad electrode 60. The n-side pad electrode 50 is formed in electrical connection with the n-side wiring portion 70a exposed from the insulation film 45b. The p-side pad electrode 60 is formed in electrical connection with the p-side wiring portion 70b. As long as the n-side pad electrode 50 and the p-side pad electrode 60 are each in a desired shape and size, they may be formed collectively. The n-side pad electrode 50 and the p-side pad electrode 60 are formed by a sputtering method, or a deposition method or the like, for example.

FIG. 13J shows the step of bonding a support plate 120 to the semiconductor structure 10 on the side with the n-side pad electrode 50 and the p-side pad electrode 60, for supporting the semiconductor structure 10 during the step of removing the growth substrate 100 to be described later. The bonding of the support plate may be achieved by depositing a resin 110 in a viscous state on one side of the semiconductor structure 10 formed with the n-side pad electrode 50 and the p-side pad electrode 60, placing the support plate 120 on the resin 110, and solidifying the resin 110. In this case, the resin 110 functions as adhesive. The resin 110 may be a polyimide- or epoxy-based resin, for example, and the support plate 120 may be a sapphire substrate, for example.

FIG. 13K shows the step of removing the growth substrate 100 to expose the second n-type semiconductor layer 12b. Specifically, the growth substrate 100 and base layer 102 shown in FIG. 13J are removed to expose the second n-type semiconductor layer 12b. When the growth substrate 100 is a GaAs substrate, the growth substrate may be removed by etching with ammonia-hydrogen peroxide (a mixture of ammonia solution, hydrogen peroxide, and pure water). In this case, the base layer 102 remains as an etch stop layer. The remaining base layer 102 is removed using hydrochloric acid. Alternatively, the base layer 102 may be removed using hydrochloric acid, to remove the growth substrate 100 therewith.

FIG. 13L shows the step of removing the second n-type semiconductor layer 12b such that at least a part of the second n-type semiconductor layer 12b remains in the center portion 10b2 of the second region 10b. For example, a mask is formed on the second n-type semiconductor layer 12b overlapping the center portion 10b2, and the second n-type semiconductor layer 12b exposed from the mask is removed, so that a portion of the second n-type semiconductor layer 12b remains in the center portion 10b2. When the second n-type semiconductor layer 12b is a GaAs layer, the second n-type semiconductor layer 12b can be removed using hydrochloric acid.

FIG. 13M shows the step of roughening the surface of the first n-type semiconductor layer 12a on the opposite side from the p-type semiconductor layer 14. The surface roughening of the first n-type semiconductor layer 12a may be achieved by wet etching using a mask. For example, a mask is formed on the second n-type semiconductor layer 12b, and the first n-type semiconductor layer 12a exposed from the mask is subjected to wet etching to roughen the surface. The mask used in the step of leaving a portion of the second n-type semiconductor layer 12b described above may be used in the step of surface roughening.

FIG. 13N shows the step of forming the holding part 80. The bonding member 80a is formed by, for example, a spin coat method so as to cover the first n-type semiconductor layer 12a and second n-type semiconductor layer 12b, and the support substrate 80b is bonded, using the bonding member 80a as adhesive. Alternatively, the holding part 80 may be formed by bonding the support substrate 80b that has the bonding member 80a that is formed on one surface thereof by a spin coat method, to the n-type semiconductor layer 12. In the case where SOG is used for the bonding member 80a in forming the holding part 80, the bonding member is heated and solidifying after bonding the support substrate 80b to the n-type semiconductor layer 12.

FIG. 13O shows the step of removing the support plate 120 bonded in the step shown in FIG. 13J. The support plate 120 may be removed by dissolving the resin 110. After that, the structure is divided into individual pieces, whereby the light-emitting elements 1 can be manufactured.

In addition to the above embodiments, the following aspects are further disclosed.

### Aspect 1

A light-emitting element comprising:
a semiconductor structure including an n-type semiconductor layer including a first n-type semiconductor layer and a second n-type semiconductor layer, an active layer, and a p-type semiconductor layer, the active layer being located between the n-type semiconductor layer and the p-type semiconductor layer in a thickness direction;
an n-side electrode electrically connected to the n-type semiconductor layer; and
a p-side electrode electrically connected to the p-type semiconductor layer, wherein the active layer emits red light having a peak wavelength within a range of 620 nm or more and 700 nm or less,
the semiconductor structure includes a first region and a second region in a plan view,
the first region is a region where the p-type semiconductor layer and the active layer are located, and the second region is a region other than the first region,
the first n-type semiconductor layer is located in the first region and the second region,
the second n-type semiconductor layer is located on the first n-type semiconductor layer at an opposite side from the p-type semiconductor layer side of the first n-type semiconductor layer so as to overlap the first n-type semiconductor layer at least in a part of the second region in a plan view,
the second n-type semiconductor layer has a smaller band gap energy than the first n-type semiconductor layer,
the first n-type semiconductor layer located in the second region has an opening that exposes the second n-type semiconductor layer, and
the n-side electrode is electrically connected to the second n-type semiconductor layer in the opening.

### Aspect 2

The light-emitting element according to Aspect 1, wherein the second n-type semiconductor layer is not located in the first region in a plan view.

### Aspect 3

The light-emitting element according to Aspect 1 or 2, wherein the second n-type semiconductor layer is partly located in the first region in a plan view.

### Aspect 4

The light-emitting element according to any one of Aspects 1 to 3, wherein a thickness of the second n-type semiconductor layer is less than a thickness of the first n-type semiconductor layer in the second region.

### Aspect 5

The light-emitting element according to any one of Aspects 1 to 4, wherein the second region where the second n-type semiconductor layer is located is surrounded by the first region in a plan view.

### Aspect 6

The light-emitting element according to any one of Aspects 1 to 5, wherein the second n-type semiconductor layer is positioned in a center region of the light-emitting element in a plan view.

### Aspect 7

The light-emitting element according to any one of Aspects 1 to 5, wherein the first region is a region including a center of the light-emitting element in a plan view, and the second n-type semiconductor layer does not overlap the center of the light-emitting element in a plan view.

### Aspect 8

The light-emitting element according to Aspect 7, wherein the second region includes an outer peripheral portion and an extended portion that is continuous with the outer peripheral portion and extends from the outer peripheral portion toward the center of the light-emitting element in a plan view, the second n-type semiconductor layer being located inside the extended portion in a plan view.

### Aspect 9

The light-emitting element according to Aspect 8, wherein an area of the second n-type semiconductor layer is 50% or more and 70% or less of an area of the extended portion, in a plan view.

### Aspect 10

The light-emitting element according to any one of Aspects 1 to 9, wherein the first n-type semiconductor layer has a rough surface on an opposite side from the p-type semiconductor layer in a portion where the first n-type semiconductor layer does not overlap the second n-type semiconductor layer.

### Aspect 11

The light-emitting element according to any one of Aspects 1 to 10, wherein an area of the second n-type semiconductor layer is 10% or more and 20% or less of an area of the second region, in a plan view.

### Aspect 12

The light-emitting element according to any one of Aspects 1 to 11, wherein the first n-type semiconductor layer comprises a layer containing either an AlGaInP-based material or an AlGaInP-based material, and the second n-type semiconductor layer contains an AlGaAs-based material.

### Aspect 13

The light-emitting element according to any one of Aspects 1 to 12, wherein an area of the second n-type semiconductor layer is 3% or more and 10% or less of an area of the light-emitting element, in a plan view.

The light-emitting element of the present disclosure efficiently emits red light having a peak wavelength within a range of 620 nm or more and 700 nm or less, and is used as the light source of an indicator or traffic light, car lamps, or the light source or backlight of an LED display, for example.

What is claimed is:

1. A light-emitting element comprising:
a semiconductor structure comprising:
an n-type semiconductor layer comprising a first n-type semiconductor layer and a second n-type semiconductor layer,
an active layer, and
a p-type semiconductor layer, wherein:
the active layer is located between the n-type semiconductor layer and the p-type semiconductor layer in a thickness direction;
an n-side electrode electrically connected to the n-type semiconductor layer; and
a p-side electrode electrically connected to the p-type semiconductor layer, wherein:
the active layer is configured to emit red light having a peak wavelength within a range of 620 nm or more and 700 nm or less,
the semiconductor structure comprises a first region and a second region in a plan view, the first region being a region where the p-type semiconductor layer and the active layer are located, and the second region being a region other than the first region,
the first n-type semiconductor layer is located in the first region and the second region,
the second n-type semiconductor layer is located on the first n-type semiconductor layer at a side opposite a p-type semiconductor layer side of the first n-type semiconductor layer, so as to overlap the first n-type semiconductor layer at least in a part of the second region in a plan view,
a band gap energy of the second n-type semiconductor layer is smaller than a band gap energy of the first n-type semiconductor layer,
a portion of the first n-type semiconductor layer located in the second region has an opening through which the second n-type semiconductor layer is exposed, and
the n-side electrode is electrically connected to the second n-type semiconductor layer in the opening.

2. The light-emitting element according to claim 1, wherein the second n-type semiconductor layer is not located in the first region in a plan view.

3. The light-emitting element according to claim 1, wherein the second n-type semiconductor layer is partly located in the first region in a plan view.

4. The light-emitting element according to claim 1, wherein a thickness of the second n-type semiconductor layer is less than a thickness of the first n-type semiconductor layer in the second region.

5. The light-emitting element according to claim 2, wherein a thickness of the second n-type semiconductor layer is less than a thickness of the first n-type semiconductor layer in the second region.

6. The light-emitting element according to claim 3, wherein a thickness of the second n-type semiconductor layer is smaller than a thickness of the first n-type semiconductor layer in the second region.

7. The light-emitting element according to claim 1, wherein a portion of the second region where the second n-type semiconductor layer is located is surrounded by the first region in a plan view.

8. The light-emitting element according to claim 2, wherein a portion of the second region where the second n-type semiconductor layer is located is surrounded by the first region in a plan view.

9. The light-emitting element according to claim 3, wherein a portion of the second region where the second n-type semiconductor layer is located is surrounded by the first region in a plan view.

10. The light-emitting element according to claim 1, wherein the second n-type semiconductor layer is positioned in a center region of the light-emitting element in a plan view.

11. The light-emitting element according to claim 2, wherein the second n-type semiconductor layer is positioned in a center region of the light-emitting element in a plan view.

12. The light-emitting element according to claim 3, wherein the second n-type semiconductor layer is positioned in a center region of the light-emitting element in a plan view.

13. The light-emitting element according to claim 1, wherein:
the first region is a region including a center of the light-emitting element in a plan view, and
the second n-type semiconductor layer does not overlap the center of the light-emitting element in a plan view.

14. The light-emitting element according to claim 13, wherein:
the second region includes:
an outer peripheral portion, and
an extended portion that is continuous with the outer peripheral portion and extends from the outer peripheral portion toward the center of the light-emitting element in a plan view,
the second n-type semiconductor layer being located inside the extended portion in a plan view.

15. The light-emitting element according to claim 14, wherein an area of the second n-type semiconductor layer is 50% or more and 70% or less of an area of the extended portion, in a plan view.

16. The light-emitting element according to claim 1, wherein the first n-type semiconductor layer has a rough surface on a side opposite a p-type semiconductor layer side of the first n-type semiconductor layer in a portion where the first n-type semiconductor layer does not overlap the second n-type semiconductor layer.

17. The light-emitting element according to claim 1, wherein an area of the second n-type semiconductor layer is 10% or more and 20% or less of an area of the second region, in a plan view.

18. The light-emitting element according to claim 1, wherein the first n-type semiconductor layer comprises a layer containing either an AlGaInP-based material or an AlGaInP-based material, and the second n-type semiconductor layer contains an AlGaAs-based material.

19. The light-emitting element according to claim 1, wherein an area of the second n-type semiconductor layer is 3% or more and 10% or less of an area of the light-emitting element, in a plan view.
